(19) United States
(12) Patent Application Publication
(10) Pub. No.: US 2012/0273638 A1
(43) Pub. Date: Nov. 1, 2012

(54) HARD DISK DRIVE BRACKET

(75) Inventor: ZHENG-HENG SUN, Tu-Cheng (TW)

(73) Assignee: HON HAI PRECISION INDUSTRY CO., LTD., Tu-Cheng (TW)

(21) Appl. No.: 13/107,969

(22) Filed: May 16, 2011

(30) Foreign Application Priority Data
Apr. 27, 2011 (CN) 201110106727.4

(51) Int. Cl. H05K 7/00

(52) U.S. Cl. 248/309.1

(57) ABSTRACT

A hard disk drive (HDD) bracket includes a frame and a handle. The frame includes two arms each defining a slot in an inner surface. An opening is defined in an end of the frame and communicating with the slots, for opposite sides of a HDD to enter the slots through the opening. The handle is pivotably mounted to the end of the frame to cover or uncover the opening.

### BACKGROUND

1. Technical Field

The present disclosure relates to a hard disk drive (HDD) bracket for mounting an HDD.

2. Description of Related Art

HDDs are generally received in brackets firstly, and then received in a rack of a chassis. In most cases, HDDs are directly fixed to the brackets with screws, which is inconvenient and time-consuming for assembly or disassembly.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a hard disk drive (HDD) bracket, together with an HDD.

FIGS. 2 and 3 are assembled, isometric views of FIG. 1, showing different states of use.

FIG. 4 is an enlarged view of the circled portion IV of FIG. 2.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

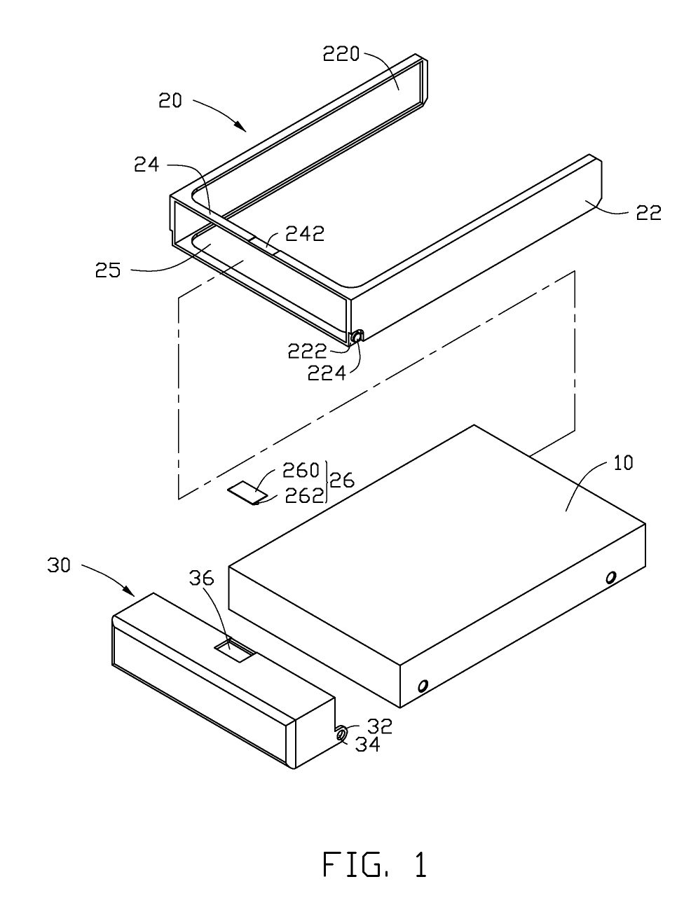

Referring to FIG. 1, an exemplary embodiment of a hard disk drive (HDD) bracket for fixing an HDD 10 includes a frame 20 and a handle 30.

The frame 20 includes two arms 22, two flanges 24 respectively perpendicularly connected between tops and bottoms of front ends of the arms 22, and a fixing piece 26. Each arm 22 longitudinally defines a slot 220 in an inner surface, and a depressed portion 222 in an outer surface adjacent to the bottom flange 24. Two pins 224 extend from the bottom wall of the depressed portions 222. An opening 25 communicating with the slots 22 is bounded by the flanges 24 and the ends of the arms 22. The top flange 24 defines a recess 242 in a center of a top of the flange 24. The fixing piece 26 includes a plate 260 fixed in the recess 242 by soldering a rear side of the plate 260, and two substantially wedge-shaped latches 262 extending down from opposite ends of the a front side of the plate 260. The latches 262 are located in front of the flanges 24.

The handle 30 is substantially rectangular. Two tabs 32 extend backward from opposite ends of the handle 30, adjacent to a bottom of the handle 30. A through hole 34 is defined in each tab 32. A latching slot 36 is defined in a top of the handle 30, adjacent to a back side of the handle 30.

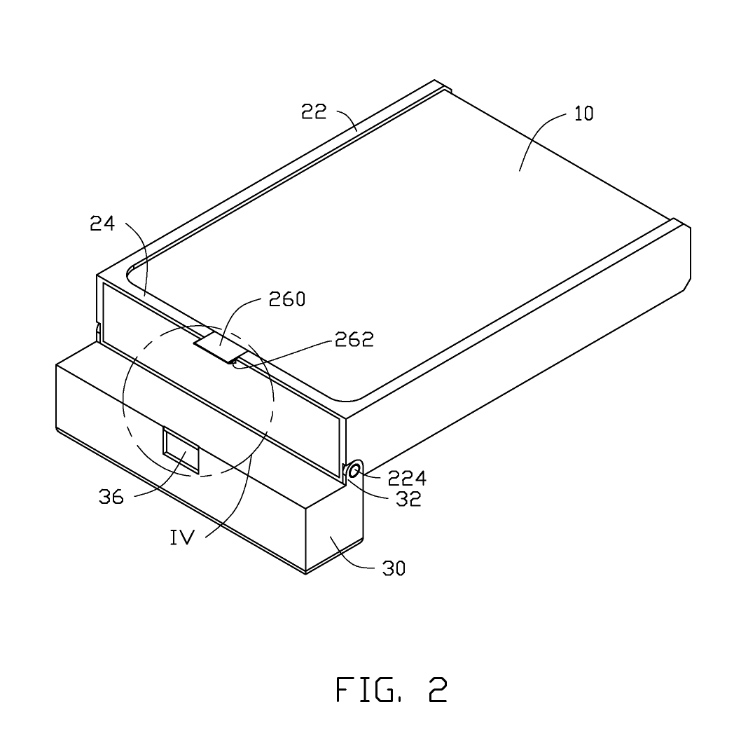

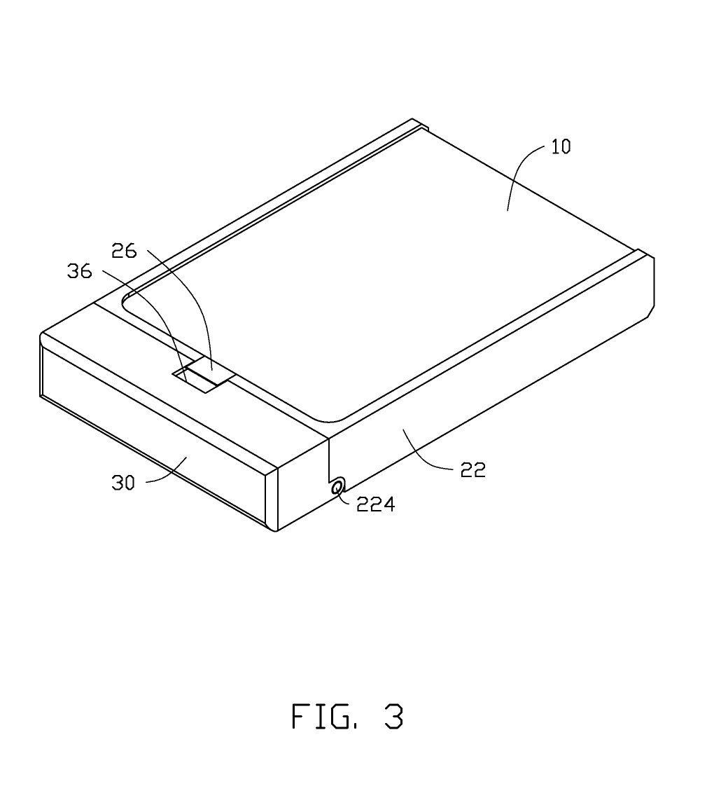

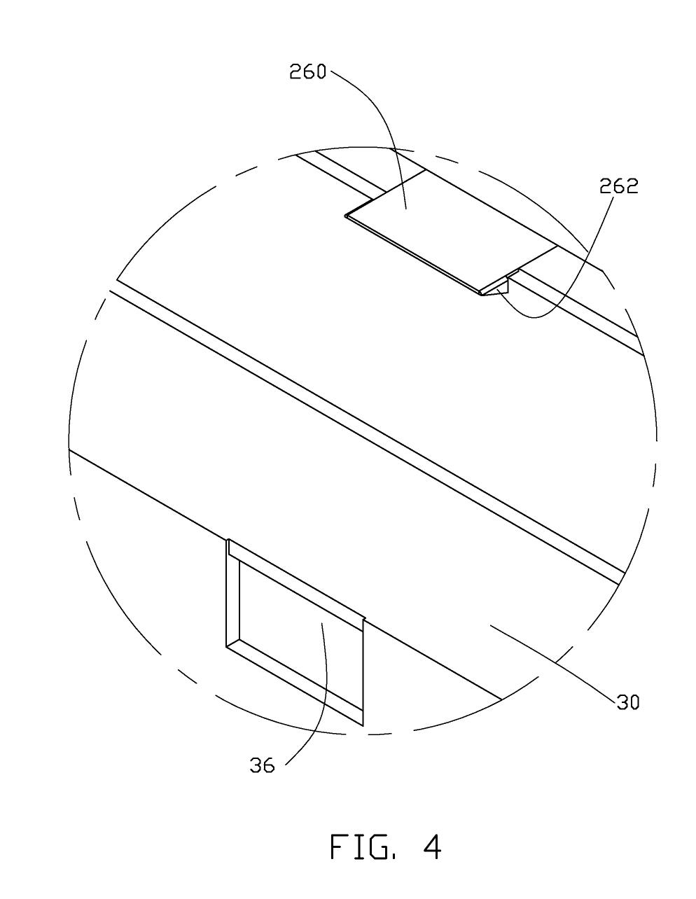

Referring to FIGS. 2 to 4, in assembly, the tabs 32 of the handle 30 are received in the depressed portions 222 of the frame 20, and the pins 224 of the arms 22 are engaged in the through holes 34 of the corresponding tabs 32, to pivotably mount the handle 30 to the front end of the frame 20.

In use, the HDD 10 is inserted into the frame 20 through the opening 25 and is sandwiched between the arms 22, with opposite sides of the HDD 10 engaging in the corresponding slots 220. The handle 30 is pivoted toward the fixing piece 26, until the latches 262 of the fixing piece 26 are engaged in the latching slot 36 of the handle 30 to be blocked by a rear wall bounding the latching slot 36, for preventing the handle 30 from pivoting about the pins 224.

In disengaging the HDD 10, the handle 30 is moved away from the fixing piece 26. Thereby, the latches 262 are disengaged from the latching slot 36, and the HDD 10 is ready to be removed from the frame 20 through the opening 25.

It is believed that the present embodiments and their advantages will be understood from the foregoing description, and they will be apparent that various changes may be made thereto without departing from the spirit and scope of the description or sacrificing all of their material advantages, the examples hereinbefore disclosed merely being exemplary embodiments.

What is claimed is:

1. A hard disk drive (HDD) bracket comprising:
a frame comprising two arms each longitudinally defining a slot in an inner surface, the frame defining an opening in a front end, communicating with the slots of the arms, for opposite sides of a HDD to enter the slots through the opening; and
a handle pivotably mounted to the front end of the frame to cover or uncover the opening.

2. The HDD bracket of claim 1, wherein two flanges substantially perpendicularly connected between tops and bottoms of the front ends of the arms, the opening is bounded by the flanges and the front ends of the arms.

3. The HDD bracket of claim 2, wherein a pin extends from an outer surface of each arm, and adjacent to one of the flanges, two tabs extend back from opposite ends of the handle, each tab defines a through hole for receiving one of the pins.

4. The HDD bracket of claim 3, wherein a fixing piece extends from the other of the flanges, the handle defines a latching slot for latching the fixing piece.

5. The HDD bracket of claim 4, wherein two latches extend down from a front side of the fixing piece to engage in the latching slot of the handle.
